(19) United States
(12) Patent Application Publication
(10) Pub. No.: US 2024/0363919 A1
(43) Pub. Date: Oct. 31, 2024

(54) Immersion Cooling of Battery Cells with Passage Design between Cells

(71) Applicant: Caterpillar lnc., Peoria, IL (US)

(72) Inventors: Peitong JIN, Dunlap, IL (US); Craig P. HITTLE, Dunlap, IL (US)

(73) Assignee: Caterpillar lnc., Peoria, IL (US)

(21) Appl. No.: 18/306,828

(22) Filed: Apr. 25, 2023

(51) Int. Cl. H01M 10/6556; H01M 10/04; H01M 10/613; H01M 10/6555; H01M 50/204; H05K 7/20

(52) U.S. Cl. CPC H01M 10/6556; H01M 10/0481; H01M 10/613; H01M 10/6555; H01M 50/204; H05K 7/203

(57) ABSTRACT

Immersion cooling of battery cells of a battery module may include a compression plate having cell engaging surfaces on either side with cooling fluid channels defined therein and extending from channel inlets at a plate bottom edge to channel outlets at a plate top edge. The compression plate is disposed between a pair of adjacent battery cells with the cell engaging surfaces facing and engaging the cell casings of the battery cells. The cooling fluid channels may cause cooling fluid entering through the channel inlets to flow over the cell casings and dissipate heat from the battery cells, and to discharge from the cooling fluid channels through the channel outlets. The cooling fluid may then flow over cell top walls of the battery cells to a housing outlet port and out of the module housing.

### TECHNICAL FIELD

The present disclosure relates generally to battery cells and, more particularly, to cooling of battery cells by immersion with cooling fluid flow between adjacent battery cells in a battery module.

### BACKGROUND

Machines such as hydraulic excavators, articulated trucks, locomotives, off-site generators and the like may be powered by large battery modules that are carried onboard. The battery modules may be fabricated with battery cells that are arranged side-by-side and that can be connected in series for higher voltage, in parallel for higher current capability, or in a combination thereof depending on the power requirements for a particular machine in which the battery modules are implemented. Compression foam, rubber or other compressible insulating material may be provided between adjacent battery cells to dampen vibration while allowing for some cell case swelling of the battery cells. Cell case swelling may occur due to thermal expansion at elevated temperatures. Swelling can also be caused by internal cell gas pressure build up from the electrolyte as batteries age and the chemical reactions that produce power no longer fully complete resulting the creation of gases, or by expansion of the active material layers within the cells. By using compressible materials, compression loading on the battery cells due to cell case swelling may be controlled and limited to avoid damage to the battery cells.

The temperature of the battery modules and the battery cells fluctuates during the charge and discharge cycling of the battery modules. High temperatures and non-uniform temperatures of the battery module can shorten the life of the battery module through the charge/discharge cycles and battery cell overheating that can lead to thermal runaway. Battery life may be improved by maintaining the battery cells within a desired temperature range during the cycling events. One approach for regulating temperatures in previously known battery modules entails installing a cooling plate against the bottom surfaces of the battery cells. Cooling fluid circulates through the cooling plate to draw heat away from the battery cells at the bottom surfaces, but the battery cells still experience high temperatures near the top of the battery module. The compression material substantially prevents fluid flow over the surfaces of the side walls of the battery cells.

As an example, U.S. Pat. Appl. Publ. No. 2020/0058974 A1 by Lim et al. discloses a battery module for a vehicle that includes a cell assembly that has a plurality of battery cells stacked on top of each other in one direction. A cooling channel integrated plate is positioned on either upper or lower portions of the cell assembly, or both, to face the cell assembly in a direction that is perpendicular to the direction in which the battery cells are stacked. The cooling channel integrated plate includes a cooling passage formed therein and cooling water flows through the cooling passage. A thermally conductive adhesive layer adheres the cell assembly and the cooling channel integrated plate to each other.

### SUMMARY OF THE DISCLOSURE

In one aspect of the present disclosure, a battery module is disclosed. The battery module may include a module housing having a housing bottom wall and a first housing inlet port, and a base plate disposed within the module housing on the housing bottom wall. The base plate may have a first base plate inlet port fluidly connected to the first housing inlet port and a first plurality of fluid discharge slots through a base plate top wall, wherein cooling fluid from the first housing inlet port is communicated through the first base plate inlet port, flows through a base plate interior and is discharged from the base plate through the first plurality of fluid discharge slots. The battery module may further include a first plurality of battery cells arranged in a first row and disposed within the module housing and on the base plate top wall, and a first plurality of compression plates, wherein each of the first plurality of compression plates is disposed between adjacent battery cells in the first row and aligned with a corresponding one of the first plurality of fluid discharge slots. Each of the first plurality of compression plates may have a first cell engaging surface facing and engaging a first cell casing of a first adjacent battery cell and having a first cooling fluid channel defined therein and extending from proximate the base plate top wall to proximate a first cell top wall of the first adjacent battery cell, and each of the first plurality of compression plates may have a second cell engaging surface facing and engaging a second cell casing of a second adjacent battery cell and having a second cooling fluid channel defined therein and extending from proximate the base plate top wall to proximate a second cell top wall of the second adjacent battery cell. The cooling fluid discharged from the corresponding one of the first plurality of fluid discharge slots may enter the first cooling fluid channel and the second cooling fluid channel, flow over the first cell casing and the second cell casing, respectively, and dissipate heat from the adjacent battery cells, and discharge from the first cooling fluid channel and the second cooling fluid channel proximate the first cell top wall and the second cell top wall.

In another aspect of the present disclosure, a compression plate for a battery module having a plurality of battery cells arranged in a row within a module housing is disclosed. The compression plate may include a first cell engaging surface having a first cooling fluid channel defined therein and extending from a first channel inlet at a plate bottom edge to a first channel outlet at a plate top edge, and a second cell engaging surface having a second cooling fluid channel defined therein and extending from a second channel inlet at the plate bottom edge to a second channel outlet at the plate top edge. When the compression plate is disposed between a pair of adjacent battery cells, the first cell engaging surface faces and engages a first cell casing of a first battery cell of the pair of adjacent battery cells and the second cell engaging surface faces and engages a second cell casing of a second battery cell of the pair of adjacent battery cells. The first cooling fluid channel and the second cooling fluid channel may cause cooling fluid entering through the first channel inlet and the second channel inlet to flow over the first cell casing and the second cell casing, respectively, and dissipate heat from the pair of adjacent battery cells, and to discharge from the first cooling fluid channel and the second cooling fluid channel through the first channel outlet and the second channel outlet.

In a further aspect of the present disclosure, a method for immersive cooling of a plurality of battery cells arranged in a row within a module housing of a battery module is disclosed. Compression plates are disposed between adjacent pairs of battery cells with first cell engaging surfaces facing and engaging first cell casings of first adjacent battery cells and having first cooling fluid channels defined therein and extending from plate bottom edges to plate top edges and second cell engaging surfaces facing and engaging second cell casings of second adjacent battery cells and having second cooling fluid channels defined therein and extending from the plate bottom edges to the plate top edges. The method may include injecting cooling fluid into a housing inlet port of the module housing, communicating the cooling fluid to a base plate inlet port of a base plate on which the plurality of battery cells is disposed, discharging the cooling fluid through fluid discharge slots in a base plate top wall of the base plate, wherein the compression plates between the adjacent pairs of battery cells are aligned with corresponding fluid discharge slots, engaging the first cell casings and the second cell casings of the adjacent pairs of battery cells with the cooling fluid flowing through the first cooling fluid channels and the second cooling fluid channels and transferring heat from the adjacent pairs of battery cells to the cooling fluid, and causing the cooling fluid to flow over cell top walls of the plurality of battery cells to a housing outlet port of the module housing.

Additional aspects are defined by the claims of this patent.

### BRIEF DESCRIPTION OF THE DRAWINGS

FIG. 1 is an isometric view of a battery module in accordance with the present disclosure;

FIG. 2 is an isometric view of a battery cell of the battery module of FIG. 1;

FIG. 3 is a side view of a pair of adjacent battery cells, a compression plate and portions of a housing wall and a base plate of the battery module of FIG. 1;

FIG. 4 is a top view of the base plate of the battery module of FIG. 1;

FIG. 5 is the top view of the base plate of FIG. 4 with a base plate top wall removed to reveal the interior;

FIG. 6 is a side view of an embodiment of the compression plate of the battery module of FIG. 1;

FIG. 7 is a partial isometric view of an alternative embodiment of the compression plate;

FIG. 8 is a partial isometric view of another alternative embodiment of the compression plate;

FIG. 9 is a partial isometric view of a further alternative embodiment of the compression plate; and

FIG. 10 is a flow diagram of an immersive cooling routine in accordance with the present disclosure for the battery module of FIG. 1.

### DETAILED DESCRIPTION

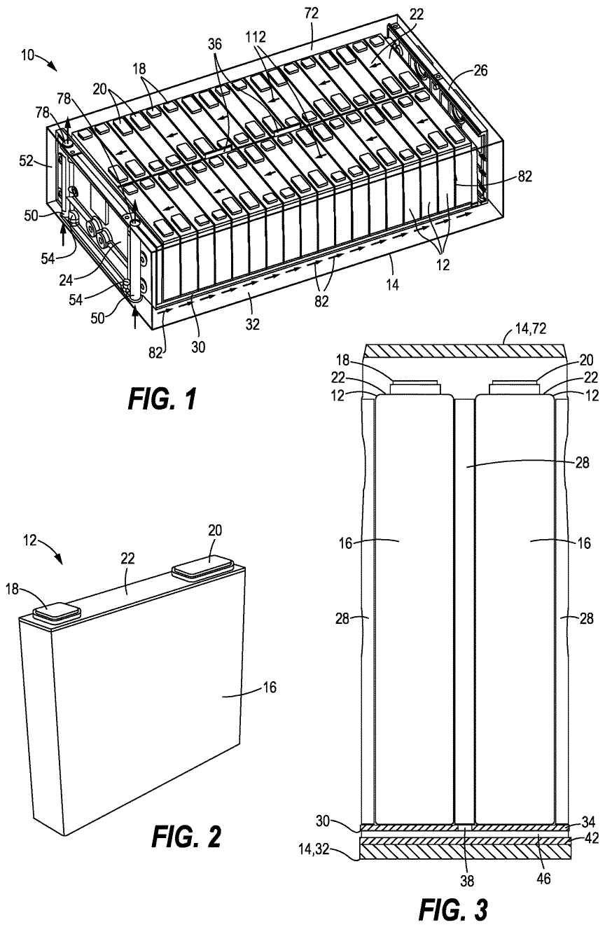

FIG. 1 illustrates an embodiment of a battery module 10 in accordance with the present disclosure that provides immersive cooling of a plurality of battery cells 12 installed therein. The battery module 10 includes an outer module housing 14 that is shown transparently to reveal the battery cells 12 and other components housed therein. The battery cells 12 are arranged side-by-side in two rows within the module housing 14 in this embodiment, but alternative arrangements with a single row or more that two rows of battery cells 12 are contemplated. An exemplary battery cell 12 is illustrated in FIG. 2. Each battery cell 12 may be a hexahedron with an outer cell casing 16 and battery terminals 18, 20 located on a cell top wall 22. The cell casing 16 is generally rigid, but is subjected to cell case swelling due to conditions such as thermal expansion, internal cell gas buildup, and expansion of the active material layers within the cell over time. The battery terminals 18, 20 of the battery cells 12 may be connected in series, in parallel or in combinations thereof to provide the required power for a particular machine in which the battery module 10 is installed. The terminal connections (not shown) may be contained within the module housing 14, with an external wiring connection (not shown) being provided on an exterior of the module housing 14 and sealed to prevent leakage from the interior of the module housing 14.

Returning to FIG. 1, the rows of battery cells 12 are disposed within the module housing 14 between a first end bracket 24 and a second end bracket 26. To reduce vibration of the battery cells 12, compression plates 28 are installed between each pair of adjacent battery cells 12 as shown in greater detail in FIG. 3. The compression plates 28 may engage facing surfaces of the adjacent battery cells 12 to substantially prevent relative movement of the battery cells 12 and prevent contact between the battery cells 12. The compression plates 28 may be fabricated from foam, rubber or other types of compressible materials. The compressible material may be stiff enough to resist vibratory movement of the battery cells 12 without being too hard so that the compression plates 28 can compress to accommodate cell case swelling while controlling or limiting compression loading on the cell casings 16. Exampled of such materials include rubber foams, fiber mats, silicone or silicone foam, epoxy or epoxy foam, polyurethane foam and the like.

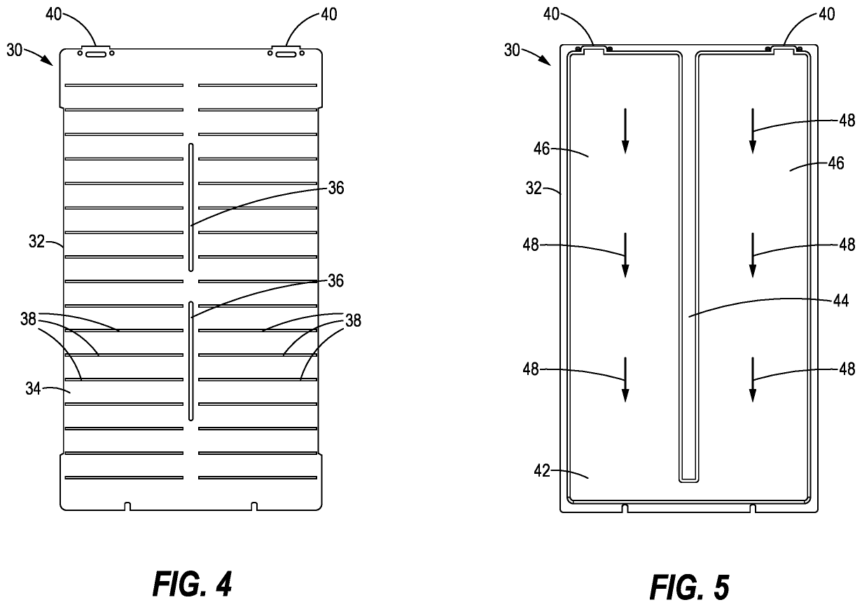

Returning again to FIG. 1, within the module housing 14, the rows of battery cells 12 sit atop a base plate 30 disposed on a housing bottom wall 32 within the module housing 14 and between the end brackets 24, 26. The base plate 30 is shown in greater detail in FIGS. 4 and 5. Referring to FIG. 4, the base plate 30 may be hollow and have a base plate top wall 34 upon which the battery cells 12 are positioned. In the illustrated embodiment, the base plate 30 is configured to support two rows of battery cells 12 as arranged in FIG. 1. The base plate 30 has a base plate top wall 34 that may have row separator flanges 36 extending upward there from to separate the rows of battery cells 12. The base plate top wall 34 has a plurality of fluid discharge slots 38 extending therethrough from an interior of the base plate 30 to a top surface of the base plate top wall 34. The fluid discharge slots 38 are arranged in rows corresponding to the rows of battery cells 12 so that each of the fluid discharge slots 38 is positioned between each pair of adjacent battery cells 12 and under the compression plate 28 disposed therebetween as shown in FIG. 3.

Returning to FIG. 4, cooling fluid may be supplied to the base plate 30 at one or more base plate inlet ports 40 that may be located proximate the first end bracket 24 within the module housing 14. The cooling fluid may be a dielectric fluid such as, for example, hydrocarbon oil that is non-conductive and non-flammable, and that may provide good heat transfer for removing heat from the battery cells 12. In the illustrated embodiment, one base plate inlet port 40 is provided for each row of fluid discharge slots 38. FIG. 5 illustrates the base plate 30 with the base plate top wall 34 removed to reveal the interior of the base plate 30 and a base plate bottom wall 42. The base plate bottom wall 42 may include a raised base plate divider 44 that may extend upward to a bottom surface of the base plate top wall 34 to define separate fluid flow channels 46 that each correspond to a row of fluid discharge slots 38. Arrows 48 indicate fluid flow within the fluid flow channels 46 from the base plate inlet ports 40 toward the second end bracket 26.

The illustrated arrangement of rows of fluid discharge slots 38, base plate inlet ports 40 and fluid flow channels 46 is exemplary, and arrangements as implemented may be dictated by the operating requirements and cooling requirements for a particular implementation of a battery module 10 in accordance with the present disclosure. For example, each row of fluid discharge slots 38 may correspond to multiple rows of battery cells 12. A number of base plate inlet ports 40 and fluid flow channels 46 may be greater than or less than the number of rows of battery cells 12 and fluid discharge slots 38. Those skilled in the art will understand that such alternatives may be implemented as required for particular implementations, and such alternatives are contemplated by the inventors as having use in battery modules 10 in accordance with the present disclosure.

Cooling fluid for the base plate 30 may be provided through the module housing 14 and the first end bracket 24 as shown in FIG. 1. The module housing 14 may have one or more housing inlet ports 50 defined therein in the housing bottom wall 32 or a housing end wall 52. The housing inlet ports 50 may be configured for attachment of a conduit or hose (not shown) from a cooling fluid source (not shown) such as a coolant pump providing the cooling fluid under pressure. The first end bracket 24 may have bracket cooling fluid passages 54 corresponding to the housing inlet ports 50 and placing the housing inlet ports 50 in fluid communication with the base plate inlet ports 40 of the base plate 30 so that the cooling fluid from the cooling fluid source is communicated to the interior of the base plate 30.

As discussed above, some prior battery modules have battery cells sitting on a cooling plate that circulates cooling fluid to draw heat from the bottoms of the battery cells. The cooling fluid in most cases does not circulate outside the cooling plate, thus the side walls and top walls of the battery cells do not have heat drawn away by a cooling medium. Additionally, compression plates in such battery modules have planar surfaces that are in surface-to-surface contact with corresponding surfaces of the adjacent battery cells, thereby substantially preventing fluid flow therebetween.

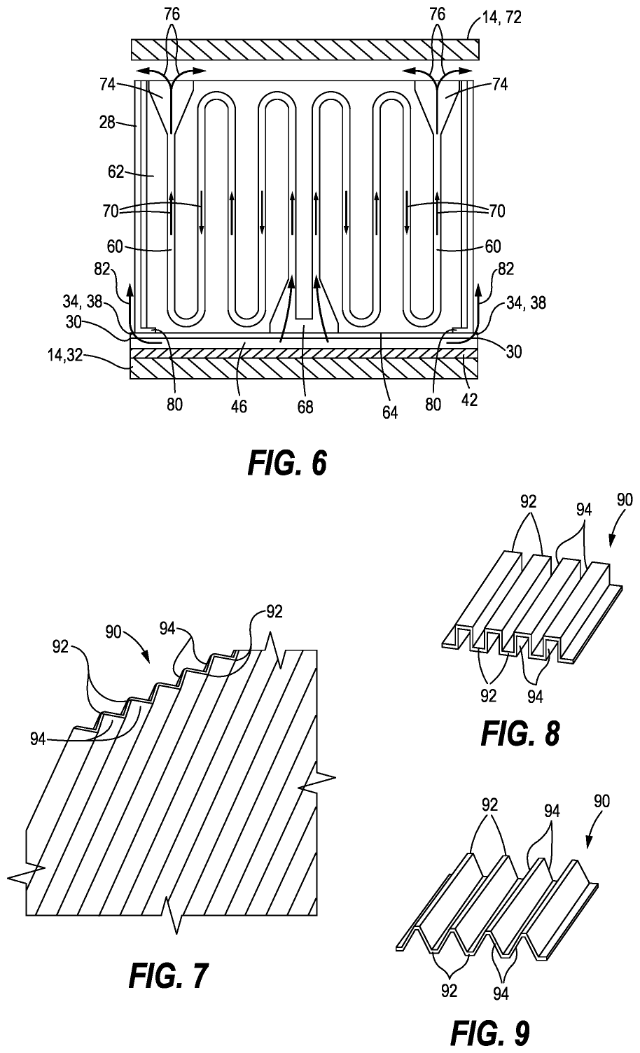

In the battery module 10 in accordance with the present disclosure, the compression plates 28 are configured to allow flow of cooling fluid from the fluid discharge slots 38 to flow over the surfaces of the cell casing 16 of the battery cells 12 and draw heat away from the battery cells 12 from locations other than their bottoms. FIG. 6 illustrates one embodiment of the compression plate 28 wherein cooling fluid channels 60 are formed in the cell engaging surfaces 62 of the compression plate 28 that are in surface-to-surface contact with the cell casings 16 of the adjacent battery cells 12. The cooling fluid channels 60 extend from a plate bottom edge 64 to a plate top edge 66. While one side of the compression plate 28 shown, those skilled in the art will understand that the compression plate 28 may be symmetrical with a similar cooling fluid channel 60 formed in the cell engaging surface 62 on the opposite side of the cell engaging surface 62 illustrated in FIG. 6. The cooling fluid channels 60 are recessed into the cell engaging surfaces 62 to provide space for the cooling fluid to flow therethrough. As illustrated, the cooling fluid channel 60 has a serpentine shape with a channel inlet 68 disposed at the plate bottom edge 64 and proximate the base plate top wall 34 to receive cooling fluid from the corresponding fluid discharge slot 38. The channel inlet 68 may be configured to direct cooling fluid from the fluid discharge slot 38 to the cooling fluid channels 60 on both cell engaging surfaces 62 of the compression plate 28, or each cooling fluid channel 60 may have its own channel inlet 68 to received cooling fluid from the fluid discharge slot 38.

Cooling fluid from the fluid discharge slot 38 will flow through the cooling fluid channel 60 as indicated by arrows 70 with heat being transferred from the cell casing 16 to the cooling fluid across the width of the battery cell 12. At the downstream ends of the cooling fluid channel 60 at the plate top edge 66 of the compression plate 28 and proximate the cell top walls 22 and a housing top wall 72 of the module housing 14, the cooling fluid may be discharged into the interior of the module housing 14 at channel outlets 74 as indicated by arrows 76. After exiting the cooling fluid channels 60, the cooing fluid may flow over the cell top walls 22 and around the battery terminals 18, 20 and terminal connections of the battery cells, draw additional heat from the battery cells 12, and flow out of the module housing 14 through housing outlet ports 78 (FIG. 1) to a cooling fluid reservoir (not shown) where heat may be dissipated from the cooling fluid prior to recirculating the cooling fluid through the battery module 10.

In addition to cooling fluid flow between the battery cells 12 and the compression plates 28, the battery modules 10 in accordance with the present disclosure may facilitate cooling fluid flow around the sides of the battery cells 12 that do not face the compression plates 28. As shown in FIG. 6, a portion of the cooling fluid from the fluid discharge slots 38 may be routed around the battery cells 12. In the illustrated embodiment, the cell engaging surfaces 62 of the compression plate 28 may include lateral discharge slots 80 at lateral edges proximate the base plate top wall 34 and the fluid discharge slot 38. A portion of the cooling fluid may flow out of the lateral discharge slots 80 and along the lateral sides of the battery cells 12 as indicated by arrows 82. The lateral discharge slots 80 may be sized and shaped to create the desired lateral discharge of cooling fluid.

The serpentine configuration of the cooling fluid channel 60 is exemplary, and the cooling fluid channel 60 may have alternative shapes. For example, the cooling fluid channel 60 may be serpentine but oriented so the cooling fluid flows from side-to-side instead of up and down as shown in FIG. 6. The cooling fluid channels 60 may have other types of circuitous paths through the cell engaging surfaces 62 from bottom to top to provide the necessary flow of cooling fluid to draw heat away from the battery cells 12. For example, where a particular design of a battery cell 12 results in concentrated hot spots on the cell casing 16, a flow path for the cooling fluid channel 60 may be configured to route a significant amount of cooling fluid flow past the hot spot to increase the heat transfer from the hot spot to the cooling fluid. Still further, the width and depth of the cooling fluid channels 60 may be varied to achieve a desired heat transfer from the battery cells 12 to the cooling fluid. Further yet, the cross-sectional shape of the cooling fluid channels 60 may be varied as necessary, with shapes such as square, rectangular, semi-circular, triangular, trapezoidal and the like being possible. Such variations in the routing and shape of the cooling fluid channels 60 of the compression plate 28 will be apparent to those skilled in the art and are contemplated by the inventors as having use in battery modules 10 in accordance with the present disclosure.

In addition to varying the design of the cooling fluid channels 60, it is possible to modify the overall design of the compression plates to facilitate cooling fluid flow over the surfaces of adjacent battery cells 12. FIG. 7 illustrates an alternative embodiment of a compression plate 90 configured to facilitate cooling fluid flow over the surfaces of adjacent battery cells 12. In this embodiment, the compression plate 90 may be fabricated from a similar material as those discussed above for the compression plates 28, or other composite, polymer and/or nonconductive materials. In other implementations, the compression plates 90 may be formed from spring steel plates. The compression plate 90 is a corrugated sheet having alternating ridges 92 and grooves 94 that may be installed between adjacent battery cells 12 in a similar manner as the compression plate 28. The ridges 92 on one side of the compression plate 90 engage the cell casing 16 of one of the adjacent battery cells 12, and the ridges 92 on the opposite side of the compression plate 90 engage the cell casing 16 of the other adjacent battery cell 12. In this way, the compression plate 90 substantially dampens vibration of the battery cells 12 while being capable of elastically deflecting to allow cell case swelling of the battery cells 12 while limiting compression loading on the cell casings 16.

When installed, the compression plate 90 is aligned with a corresponding one of the fluid discharge slots 38 of the base plate 30 and oriented with the ridges 92 and the grooves 94 extending vertically from the base plate 30 to the cell top walls 22 and the housing top wall 72. When cooling fluid is discharged from the fluid discharge slot 38, the grooves 94 function as cooling fluid channels as discussed above with the cooling fluid flowing up through the grooves 94 on both sides of the compression plate 90, contacting the cell casings 16, and drawing heat from the adjacent battery cells 12 from bottom to top. The cooling fluid exits the grooves 94 proximate the cell top walls 22. At the same time, a portion of the cooling fluid discharges laterally and flows up along the lateral sides of the battery cells 12.

The grooves 94 of the compression plate 90 as shown in FIG. 7 have a triangular shape terminating at a point at the ridges 92. The distance between adjacent ridges 92 can be varied to widen or narrow the grooves 94 and optimize heat transfer in a given implementation. Of course, the ridges 92 and the grooves 94 of the corrugated compression plate 90 may have other shapes. For example, as shown in FIG. 8, the grooves 94 may be rectangular with parallel walls terminating at ridges 92 that are planar and have a ridge width that is approximately equal to a groove width of the grooves 94. As another alternative as shown in FIG. 9, the grooves 94 may have a trapezoidal shape with the grooves 94 being tapered and terminating at planar ridges 92 with the ridge width that is less than a maximum groove width of the grooves 94. Still further, the ridges 92 and the grooves 94 may have a degree of curvature such that the corrugations are approximately sinusoidal with curved ridges 92 engaging the cell casings 16 along lines of contact. Further alternative shapes for the ridges 92 and the grooves 94 will be apparent to those skilled in the art and are contemplated by the inventors.

### INDUSTRIAL APPLICABILITY

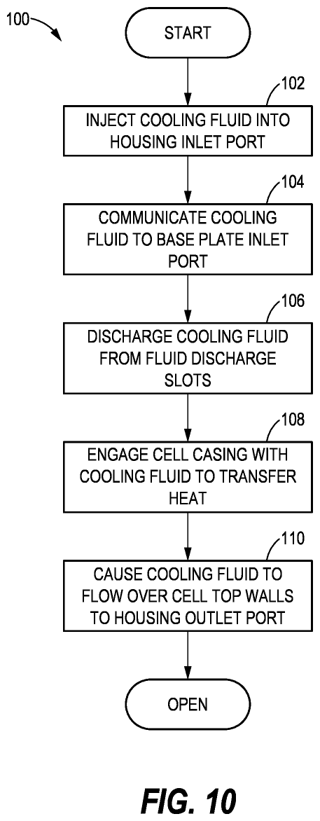

The operation of the battery module 10 to provide immersive cooling of the battery cells 12 within the battery module 10 is illustrated in FIG. 1, and a routine 100 for immersive cooling or the battery cells 12 is shown in FIG. 10. The routine 100 may begin at a block 102 where cooling fluid from the cooling fluid source is injected into the module housing 14 at the housing inlet ports 50. In this embodiment, the cooling fluid enters the housing inlet ports 50 and is communicated to the bracket cooling fluid passages 54. At a block 104, the cooling fluid is communicated to the base plate inlet ports 40 from the bracket cooling fluid passages 54 and into the interior of the base plate 30 and the fluid flow channels 46.

At a block 106, cooling fluid is discharged from the base plate 30 through the fluid discharge slots 38, and at a block 108 the discharged cooling fluid flows into channel inlets 68 and through the cooling fluid channels 60, 94 of the compression plates 28, 90 to engage the cell casings 16 and transfer heat from the side surfaces of the battery cells 12 to the cooling fluid. At the same time, a portion of the cooling fluid is discharged laterally, such as through the lateral discharge slots 80, to create cooling fluid flow (arrows 82) over the lateral sides of the battery cells 12 and cause additional heat transfer to the cooling fluid. At a block 108, as the cooling fluid exits the cooling fluid channels 60, 94 at the channel outlets 74, for example, and flows over the lateral sides of the battery cells 12 to the cell top walls 22, the area formed between the cell top walls 22 and the housing top wall 72 causes the cooling fluid to flow over the cell top walls 22 to the housing outlet ports 78 as indicated by arrows 112 and out of the module housing 14 to the cooling fluid reservoir. The cooling fluid flow over the cell top walls 22 may facilitate additional heat transfer from the cell top walls 22, the battery terminals 18, 20 and the terminal connections between the battery terminals 18, 20 to the cooling fluid.

The battery module 10 in accordance with the present disclosure provides immersive cooling of the battery cells 12 contained therein while maintaining the requisite compression and vibration dampening between the cells. The cooling fluid channels 60, 94 of the compression plates 28, 90 installed between adjacent battery cells 12 permit cooling fluid flow along the cell casings 16 to facilitate increased heat transfer from the battery cells 12 to the cooling fluid than occurs in previous battery modules having only a cooling plate drawing heat only at the bottom of battery cells. Additional flow of cooling fluid over the lateral sides, cell top walls 22 and battery terminals 18, 20 of the battery cells 12 provides further heat transfer that is not provided by previous battery modules.

While the preceding text sets forth a detailed description of numerous different embodiments, it should be understood that the legal scope of protection is defined by the words of the claims set forth at the end of this patent. The detailed description is to be construed as exemplary only and does not describe every possible embodiment since describing every possible embodiment would be impractical, if not impossible. Numerous alternative embodiments could be implemented, using either current technology or technology developed after the filing date of this patent, which would still fall within the scope of the claims defining the scope of protection.

It should also be understood that, unless a term was expressly defined herein, there is no intent to limit the meaning of that term, either expressly or by implication, beyond its plain or ordinary meaning, and such term should not be interpreted to be limited in scope based on any statement made in any section of this patent (other than the language of the claims). To the extent that any term recited in the claims at the end of this patent is referred to herein in a manner consistent with a single meaning, that is done for sake of clarity only so as to not confuse the reader, and it is not intended that such claim term be limited, by implication or otherwise, to that single meaning.

What is claimed is:

1. A battery module comprising:
a module housing having a housing bottom wall and a first housing inlet port;
a base plate disposed within the module housing on the housing bottom wall, the base plate having a first base plate inlet port fluidly connected to the first housing inlet port and a first plurality of fluid discharge slots through a base plate top wall, wherein cooling fluid from the first housing inlet port is communicated through the first base plate inlet port, flows through a base plate interior and is discharged from the base plate through the first plurality of fluid discharge slots;
a first plurality of battery cells arranged in a first row and disposed within the module housing and on the base plate top wall; and
a first plurality of compression plates, wherein each of the first plurality of compression plates is disposed between adjacent battery cells in the first row and aligned with a corresponding one of the first plurality of fluid discharge slots, wherein each of the first plurality of compression plates has a first cell engaging surface facing and engaging a first cell casing of a first adjacent battery cell and having a first cooling fluid channel defined therein and extending from proximate the base plate top wall to proximate a first cell top wall of the first adjacent battery cell, wherein each of the first plurality of compression plates has a second cell engaging surface facing and engaging a second cell casing of a second adjacent battery cell and having a second cooling fluid channel defined therein and extending from proximate the base plate top wall to proximate a second cell top wall of the second adjacent battery cell, and wherein the cooling fluid discharged from the corresponding one of the first plurality of fluid discharge slots enters the first cooling fluid channel and the second cooling fluid channel, flows over the first cell casing and the second cell casing, respectively, and dissipates heat from the adjacent battery cells, is discharged from the first cooling fluid channel and the second cooling fluid channel proximate the first cell top wall and the second cell top wall.

2. The battery module of claim 1, wherein the module housing has a first housing outlet port proximate a housing top wall, wherein the cooling fluid discharged from the first cooling fluid channel and the second cooling fluid channel of the first plurality of compression plates flows over cell top walls and terminals of the first plurality of battery cells and out of the module housing through the first housing outlet port.

3. The battery module of claim 1, wherein each of the first plurality of compression plates has lateral discharge slots proximate the corresponding one of the first plurality of fluid discharge slots so that a portion of the cooling fluid is discharged laterally and flows upward over lateral surfaces of the first cell casing and the second cell casing that are not engaged by the first cell engaging surface and the second cell engaging surface.

4. The battery module of claim 1, wherein the first plurality of compression plates are fabricated from a compressible material.

5. The battery module of claim 1, wherein the first cooling fluid channel comprises a plurality of first cooling fluid channels and the second cooling fluid channel comprises a plurality of second cooling fluid channels.

6. The battery module of claim 1, wherein each of the first plurality of compression plates comprises a corrugated sheet having alternating ridges and grooves extending from the base plate to the first cell top wall and the second cell top wall, wherein the alternating ridges of the first cell engaging surface engage the first cell casing and the grooves of the first cell engaging surface define a plurality of first cooling fluid channels, and the alternating ridges of the second cell engaging surface engage the second cell casing and the grooves of the second cell engaging surface define a plurality of second cooling fluid channels.

7. The battery module of claim 1, wherein the module housing has a second housing inlet port, the base plate has a second base plate inlet port fluidly connected to the second housing inlet port and a second plurality of fluid discharge slots through the base plate top wall, wherein the cooling fluid from the second housing inlet port is communicated through the second base plate inlet port, flows through the base plate interior and is discharged from the base plate through the second plurality of fluid discharge slots, the battery module comprising:
a second plurality of battery cells arranged in a second row and disposed within the module housing and on the base plate top wall; and
a second plurality of compression plates, wherein each of the second plurality of compression plates is disposed between the adjacent battery cells of the second row and aligned with a corresponding one of the second plurality of fluid discharge slots, wherein each of the second plurality of compression plates has the first cell engaging surface facing and engaging the first cell casing of the first adjacent battery cell and the first cooling fluid channel extending from proximate the base plate top wall to proximate the first cell top wall, wherein each of the second plurality of compression plates has the second cell engaging surface facing and engaging the second cell casing of the second adjacent battery cell and the second cooling fluid channel extending from proximate the base plate top wall to proximate the second cell top wall, and wherein the cooling fluid discharged from the corresponding one of the second plurality of fluid discharge slots enters the first cooling fluid channel and the second cooling fluid channel, flows over the first cell casing and the second cell casing, respectively, and dissipates heat from the adjacent battery cells of the second row, and is discharged from the first cooling fluid channel and the second cooling fluid channel proximate the first cell top wall and the second cell top wall.

8. A compression plate for a battery module having a plurality of battery cells arranged in a row within a module housing, the compression plate comprising:
a first cell engaging surface having a first cooling fluid channel defined therein and extending from a first channel inlet at a plate bottom edge to a first channel outlet at a plate top edge; and
a second cell engaging surface having a second cooling fluid channel defined therein and extending from a second channel inlet at the plate bottom edge to a second channel outlet at the plate top edge,
wherein, when the compression plate is disposed between a pair of adjacent battery cells, the first cell engaging surface faces and engages a first cell casing of a first battery cell of the pair of adjacent battery cells and the second cell engaging surface faces and engages a second cell casing of a second battery cell of the pair of adjacent battery cells, and wherein the first cooling fluid channel and the second cooling fluid channel cause cooling fluid entering through the first channel inlet and the second channel inlet to flow over the first cell casing and the second cell casing, respectively, and dissipate heat from the pair of adjacent battery cells, and to discharge from the first cooling fluid channel and the second cooling fluid channel through the first channel outlet and the second channel outlet.

9. The compression plate of claim 8, wherein the compression plate is fabricated from a compressible material.

10. The compression plate of claim 8, wherein the first cooling fluid channel and the second cooling fluid channel have a serpentine shape with a plurality of vertical sections for the cooling fluid to flow over the first cell casing and the second cell casing.

11. The compression plate of claim 8, wherein the first cooling fluid channel comprises a first serpentine section from the first channel inlet to the first channel outlet and a second serpentine section from the first channel inlet to a second first channel outlet at the plate top edge, and wherein the second cooling fluid channel comprises a first serpentine section from the second channel inlet to the second channel outlet and a second serpentine section from the second channel inlet to a second second channel outlet at the plate top edge.

12. The compression plate of claim 8, wherein the first cooling fluid channel comprises a plurality of first cooling fluid channels and the second cooling fluid channel comprises a plurality of second cooling fluid channels.

13. The compression plate of claim 8, comprising a corrugated sheet having alternating ridges and grooves extending from the plate bottom edge to the plate top edge, wherein the alternating ridges of the first cell engaging surface engage the first cell casing and the grooves of the first cell engaging surface define first cooling fluid channels, and the alternating ridges of the second cell engaging surface engage the second cell casing and the grooves of the second cell engaging surface define a plurality of second cooling fluid channels.

14. The compression plate of claim 8, wherein the first cooling fluid channel and the second cooling fluid channel have a triangular cross-sectional shape.

15. The compression plate of claim 8, wherein the first cooling fluid channel and the second cooling fluid channel have a rectangular cross-sectional shape.

16. The compression plate of claim 8, comprising lateral discharge slots proximate the plate bottom edge so that a portion of the cooling fluid is discharged laterally and flows upward over lateral surfaces of the first cell casing and the second cell casing that are not engaged by the first cell engaging surface and the second cell engaging surface.

17. A method for immersive cooling of a plurality of battery cells arranged in a row within a module housing of a battery module, wherein compression plates are disposed between adjacent pairs of battery cells with first cell engaging surfaces facing and engaging first cell casings of first adjacent battery cells and having first cooling fluid channels defined therein and extending from plate bottom edges to plate top edges and second cell engaging surfaces facing and engaging second cell casings of second adjacent battery cells and having second cooling fluid channels defined therein and extending from the plate bottom edges to the plate top edges, the method comprising:
injecting cooling fluid into a housing inlet port of the module housing;
communicating the cooling fluid to a base plate inlet port of a base plate on which the plurality of battery cells is disposed;
discharging the cooling fluid through fluid discharge slots in a base plate top wall of the base plate, wherein the compression plates between the adjacent pairs of battery cells are aligned with corresponding fluid discharge slots;
engaging the first cell casings and the second cell casings of the adjacent pairs of battery cells with the cooling fluid flowing through the first cooling fluid channels and the second cooling fluid channels and transferring heat from the adjacent pairs of battery cells to the cooling fluid; and
causing the cooling fluid to flow over cell top walls of the plurality of battery cells to a housing outlet port of the module housing.

18. The method for immersive cooling of claim 17, discharging a portion of the cooling fluid through lateral discharge slots proximate the plate bottom edges of the compression plates so that the portion of the cooling fluid is discharged laterally and flows upward over lateral surfaces of the first cell casings and the second cell casings that are not engaged by the first cell engaging surfaces and the second cell engaging surfaces.

19. The method for immersive cooling of claim 17, wherein the cooling fluid is a dielectric fluid.

20. The method for immersive cooling of claim 17, wherein the first cooling fluid channels of the compression plates comprise a plurality of first cooling fluid channels and the second cooling fluid channels of the compression plates comprises a plurality of second cooling fluid channels.
